(19) United States
(12) Patent Application Publication
(10) Pub. No.: US 2013/0215584 A1
(43) Pub. Date: Aug. 22, 2013

(54) LAMINATE WITH INTEGRATED ELECTRONIC COMPONENT

(71) Applicants: Andreas Klein, Freigericht (DE); Eckhard Ditzel, Linsengericht (DE); Frank Krüger, Nidderau (DE); Wulf Kock, Alzenau (DE); Andreas Hinrich, Freigericht (DE)

(72) Inventors: Andreas Klein, Freigericht (DE); Eckhard Ditzel, Linsengericht (DE); Frank Krüger, Nidderau (DE); Wulf Kock, Alzenau (DE); Andreas Hinrich, Freigericht (DE)

(73) Assignee: HERAEUS MATERIALS TECHNOLOGY GMBH & CO. KG, Hanau (DE)

(21) Appl. No.: 13/880,756

(22) PCT Filed: Oct. 24, 2011
(86) PCT No.: PCT/EP2011/005340

§ 371 Date: Apr. 22, 2013

(30) Foreign Application Priority Data
Nov. 5, 2010 (DE) 10 2010 050 342.8

(51) Int. Cl. H05K 1/02; H05K 3/10

(52) U.S. Cl. CPC H05K 1/0298; H05K 3/10
USPC 361/760; 29/846

(57) ABSTRACT

The invention relates to methods for producing a laminate for contacting an electronic component, in which an insulating layer is arranged between first and second metal layers. The method includes contacting the metal layers to each other in a contact region, generating a recess in the insulating layer, laminating the metal layers to the insulating layer, generating a notch for accommodating the electronic component in the contact region in the first metal layer, inserting the electronic component in a depression in the laminate formed through a notch and recess. The electronic component is connected in a conductive manner to the second metal layer, such that an entire circumference of the electronic component is accommodated in the recess and/or notch, and at least part of the height of the electronic component is accommodated in the notch and/or recess. The invention also relates to such a laminate for contacting an electronic component.

### CROSS-REFERENCE TO RELATED APPLICATIONS

This application is a Section 371 of International Application No. PCT/EP2011/005340, filed Oct. 24, 2011, which was published in the German language on May 10, 2012, under International Publication No. WO 2012/059187 A1 and the disclosure of which is incorporated herein by reference.

### BACKGROUND OF THE INVENTION

The invention relates to a method for producing a laminate for contacting at least one electronic component, in which an insulating layer is arranged between a first metal layer and a second metal layer. The metal layers are contacted to each other in at least one contact region, at least one recess is or are generated in the insulating layer, and the metal layers are laminated to the insulating layer. The invention also relates to a laminate for contacting an electronic component. And lastly, the invention also relates to the use of the laminate.

Integrated circuits (ICs, chips) are contacted in most cases by means of a metal-coated plastic circuit board. In order to generate complex electronic circuitry, it is usually necessary to implement through-platings in the circuit substrate that is used. For example, printed circuit boards or punched-laminated substrates are used as circuit substrates.

Through-plating from top to bottom of a circuit board of this type is achieved through recesses in the circuit board. The recesses can take up conductive contacting parts of electronic components that are attached to the circuit board which extend through the recesses and thus provide a conductive connection of the two sides. Alternatively, the recesses can comprise a patent metallic layer on their surface as through-plating.

A method for producing a metal-plastic laminate is known from DE 198 52 832 A1, in which a metal foil is formed into a trough through embossing or deep-drawing followed by a plastic film being laminated to the formed metal foil. The metal contact surface profile remains unchanged in the process. Moreover, according to the description, a metal foil is firstly tacked to a plastic film and only then the metal foil is formed into a trough through embossing or deep-drawing. In both cases, a laminate made up of a metal foil and a plastic film is produced, in which the plastic film comprises a recess in the region of the trough. Through-plating is achieved in this context through bulging the metal foil in the region of the recess of the plastic film. The actual through-plating can be generated using another conductive layer on the plastic film that is connected in conductive manner to the metal foil in the region of the trough.

This is disadvantageous in that the application of the conductive layer necessitates a second working step. Through-plating of two metal foils that have a plastic film arranged between them is achieved through a generic method for producing a laminate for contacting an electronic component according to DE 102 05 521 A1. In this context, two metal layers are laminated to an insulating layer either sequentially or simultaneously. A first metal layer comprises an embossing or bulging, whereby lamination of a second planar metal layer to the insulating layer provides for electrical contacting of the two metal layers.

This is disadvantageous in that the inserted electronic component may overheat since the heat cannot be dissipated rapidly enough through the laminate. This can impair the function, service life, and even the performance of the electronic component, even to the point of destruction thereof.

Another disadvantage is that an electronic component protrudes from the substrate after its conductor connectors are connected to the laminate. The elevated arrangement exposes the electronic component to mechanical stresses. Brittle chips might easily be destroyed. If the electronic component is an LED, it emits light from the surface of the laminate in all directions.

It is also disadvantageous that the electronic component subsequently needs to be connected to the laminate. This necessitates an additional working step that takes additional time in mass production and thus increases the production costs markedly. Moreover, exact positioning of the electronic component may be difficult to achieve such that a certain fraction of inexactly positioned scrap is produced with the finished product and needs to be picked out subsequently.

It is the object of the invention to overcome disadvantages of the prior art. In particular, the dissipation of heat is to be improved without the laminate with the electronic component becoming too large in size. Moreover, a more stable structure is desirable as well. The structure being flatter would be expedient for the ever advancing miniaturization of components needed, for example, in the assembly of mobile phones. Provided an LED is used as electronic component, an increase in luminous efficiency would also be desirable.

### BRIEF SUMMARY OF THE INVENTION

In one embodiment, the object of the invention is met in that at least one notch for accommodating at least one electronic component is generated in the first metal layer. Also, at least one electronic component is inserted in at least one depression in the laminate formed through one notch and one recess and is connected in a conductive manner to the second metal layer, such that the entire circumference of the electronic component is accommodated fully in the recess and/or notch and at least part of the height (H) of the electronic component is accommodated in the notch and/or recess.

In this context, a preferred embodiment of the invention can provide at least one recess and one notch to be arranged to be overlapping, at least over regions thereof.

A preferred embodiment of the invention can just as well provide the metal layers to be fixed to each other in a firmly bonded manner.

Moreover, a preferred embodiment of the invention can provide the distance of the two metal layers from each other to be reduced to the extent that the two metal layers touch each other.

According to a preferred embodiment of the invention, the metal layers can be sintered using a silver sintering compound.

Moreover, a preferred embodiment of the invention can provide at least one recess to be generated in at least one contact region.

A preferred embodiment of the invention can just as well provide the laminate to be laminated to the electronic component by means of a plastic layer, at least on the side of the electronic component.

A preferred embodiment of the invention can just as well provide a lens to be attached in the region of the recess or notch, in particular above the first metal layer.

A refinement of the invention preferably provides at least one embossing and/or at least one bulging in the contact region to be generated at least in the first metal layer, whereby the distance between the two metal layers is reduced in the regions of the at least one embossing and/or bulging, preferably is reduced to a distance of zero.

A bulging shall be understood to mean that a metal layer is produced such that the shape of the bulging is predetermined without the metal layer having to be deformed or formed in order to provide the bulging. An embossing shall be understood in the present context to mean that the shape of the embossing arises through deforming a metal layer. The metal layer is planar before this process in most cases.

In this context, a preferred embodiment of the invention can provide the dimensions of at least one embossing and/or of at least one bulging sufficient for accommodating at least one electronic component, whereby at least one notch is arranged in the first metal layer in the region of an embossing and/or bulging.

In this context, a preferred embodiment of the invention can further provide that the entire circumference of the at least one electronic component is accommodated in the at least one embossing and/or bulging and that at least part of the height (H) of the electronic component is accommodated in the embossing or the bulging.

Particularly advantageous methods according to the invention can preferably provide the cross-section of at least one notch, in particular the surface area and/or the dimensions of at least one notch, to be adapted to match the electronic component or electronic components, preferably to the cross-section perpendicular to height (H) of the electronic component or electronic components.

The invention can just as well preferably provide the cross-section of at least one notch, in particular its surface area and/or dimensions, to be generated to be equal to or slightly larger than the dimensions, preferably the cross-section, of the electronic component or electronic components perpendicular to height (H).

According to an advantageous refinement, the invention can preferably provide the method to involve the use of punch-lamination for connecting the metal layers to the insulating layer and concurrently produce at least one embossing and/or at least one bulging and/or at least one notch.

A preferred embodiment of the invention can just as well provide at least one embossing and/or bulging to be produced through embossing or bending the first metal layer.

A preferred embodiment of the invention can further provide for at least one embossing and/or bulging comprising at least one notch in the first metal layer to be positioned in at least one existing recess in the insulating layer.

For connecting the metal layers, the invention can preferably provide the metal layers to be connected to each other in at least one contact region through welding, soldering, gluing with a conductive adhesive or sintering.

It is particularly preferably for the invention to provides at least one electronic component to be connected to the second metal layer by means of an electrically conductive connecting means, preferably by means of gluing, particularly preferably by means of a conductive adhesive, soldering or sintering, particularly preferably through a silver sintering compound.

Another refinement of the invention provides at least one electronic component to be connected to the first and the second metal layer by means of an electrically conductive connecting means, preferably by means of gluing, particularly preferably by means of a conductive adhesive, soldering or sintering, particularly preferably through a silver sintering compound.

It is particularly easy to implement a method according to the invention if the at least one embossing and/or at least one bulging in the first metal layer is produced in the same step, in which the electronic component is contacted to the first metal layer.

A preferred embodiment of the invention can just as well provide at least one chip, at least one LED and/or at least one sensor to be used as the at least one electronic component.

It is particularly preferably for the invention to provide at least one electronic component to be connected across much of its surface area to the second metal layer and thus to preferably be thermally well-coupled to the second metal layer.

According to a refinement, the invention preferably provides at least one embossing and/or at least one bulging and/or at least one notch and/or at least one recess to be shaped appropriately such that, in particular, the angles of the side walls with respect to the first metal layer are adjusted in such manner that the light is emitted in one direction, preferably perpendicular to the plane of the first metal layer, whereby an LED is inserted as electronic component or LEDs are inserted as electronic components.

The walls of the depression then act as a kind of reflector for the light from the LED.

In this context, the invention can preferably provide the surface of the at least one embossing and/or at least one bulging and/or at least one notch to be produced as a reflective surface, preferably by means of an optically polished stamp.

A preferred embodiment of the invention can just as well provide a plastic layer, in particular a plastic film, preferably comprising glass fibre-reinforced plastic material based on epoxy, PET or PI film, to be used as insulating layer.

Moreover, the invention can provide a layer that is thicker than the first metal layer to be used as second metal layer, whereby the second metal layer preferably is selected to be large as compared to the electronic component.

The invention can also provide at least one of the metal layers to be made from copper, aluminium and/or a copper alloy, particularly preferably from a copper-tin alloy.

A particularly preferred refinement of the invention provides at least one region of the first metal layer to be separated such that at least two regions of the first metal layer are arranged at a distance from each other and electrically insulated from each other, whereby at least one electronic component is connected to at least two regions in conductive manner, preferably through at least one bonding wire such that applying a voltage between two regions leads to an electrical current being conducted through the electronic component.

The object of the invention is also met through a laminate for contacting an electronic component, in particular produced using a method of this type, comprising a first metal layer and a second metal layer that is arranged essentially parallel to the first metal layer and is separated, in regions, from the first metal layer through an insulating layer, whereby at least one recess is provided in the insulating layer and at least one notch is provided in the first metal layer, whereby at least regions of these overlap and thus form a depression, whereby at least one electronic component is arranged in at least one depression and is/are taken up entirely with respect to its circumference in the at least one notch and/or the at least one recess, and is/are connected to the second metal layer in conductive manner, and in that the at least one electronic component is taken up at least partly, with respect to the height (H) of the electronic component, in the at least one notch and/or recess.

In this context, the invention can provide that at least one recess and one notch are arranged to be overlapping, at least over regions thereof.

Moreover, the invention can preferably provide the first metal layer to comprise at least one embossing and/or at least one bulging, whereby the metal layers are connected in electrically conductive manner in the region of the at least one embossing and/or the at least one bulging.

A further refinement of the invention provides the second metal layer to be 0.1 mm to 2 mm in thickness, preferably 0.1 mm to 0.5 mm, particularly preferably 0.3 mm.

Just as well, the first metal layer and/or the insulating layer can be provided to be 10 μm to 300 μm in thickness, preferably 50 μm to 200 μm, particularly preferably 100 μm.

Moreover, the invention can preferably provide at least one recess to be arranged in at least one embossing and/or bulging.

It may be advantageous according to the invention to provide a single electronic component in a recess.

The invention can provide that the cross-section of at least one notch, in particular the surface area and/or the dimensions of at least one notch, is/are adapted to the electronic component or electronic components, preferably to the cross-section perpendicular to height (H) of the electronic component or electronic components.

A refinement of the invention provides the cross-section of at least one notch, in particular its surface area and/or dimensions, to be equal to or slightly larger than the dimensions, preferably the cross-section of the electronic component or electronic components perpendicular to the height (H) of the electronic component or electronic components.

Moreover, the invention can preferably provide the metal layers to be connected to each other in at least one contact region through welding, soldering, gluing with a conductive adhesive or sintering.

Moreover, the invention can preferably provide at least one electronic component to be connected to the second metal layer by means of an electrically conductive connecting means, preferably by means of soldering, sintering, particularly preferably using a silver sintering compound, or by means of gluing, particularly preferably using a conductive adhesive.

The invention can further provide at least one electronic component to be connected to the first and the second metal layer by means of an electrically conductive connecting means, preferably by means of gluing, particularly preferably by means of a conductive adhesive, by means of soldering or sintering, particularly preferably using a silver sintering compound.

A refinement of the invention provides at least one electronic component to be a chip, an LED and/or a sensor.

Just as well, the invention can provide at least one electronic component to be connected across much of its surface area to the second metal layer, and thus to be well-coupled thermally to at least one metal layer, in particular to the second metal layer.

The invention can just as well provide at least one embossing and/or at least one bulging and/or at least one notch to be shaped appropriately such that, in particular, the angles of the side walls with respect to the first metal layer are adjusted in such manner that light from the at least one embossing and/or at least one bulging and/or at least one notch is emitted in one direction, preferably perpendicular to the plane of the first metal layer, whereby the electronic component is an LED or the electronic components are LEDs.

According to a refinement, the invention can preferably provide the surface of the at least one embossing and/or at least one bulging and/or at least one notch or of the depression to be a reflecting surface.

The invention can just as well preferably provide the insulating layer to be a plastic layer, in particular a plastic film, preferably comprising glass fibre-reinforced plastic material based on epoxy, PET or PI film.

It is particularly preferably for the invention to provide the second metal layer to be thicker than the first metal layer, in particular to be large as compared to the electronic component, whereby the metal layers preferably comprise copper, aluminium and/or a copper alloy, particularly preferably comprising a copper-tin alloy, or to consist of copper, aluminium and/or a copper alloy, particularly preferably a copper-tin alloy.

The invention can just as well provide at least one region of the second metal layer to be separated, such that at least two regions of the second metal layer are arranged at a distance from each other and electrically insulated from each other, whereby at least one electronic component is connected to at least two regions in conductive manner, preferably through at least one bonding wire, such that applying a voltage between at least two regions leads to an electrical current being conducted through the electronic component.

And lastly, an object of the invention is also met through the use of the laminate as circuit board, sensor, LED lamp, mobile phone component, control, regulator or mobile phone flash LED.

The invention is based on the surprising finding that connecting the electronic component directly to the second metal layer allows the electronic component to dissipate its heat directly to the second metal layer. The heat can be dissipated from there out of the laminate. It is particularly preferable, in this context, that much of the surface of the electronic component, in particular much of its external surface, is connected to the second metal layer by means of a thin layer of a connecting means with good heat conducting properties. The notch needed for insertion of the electronic component can be produced particularly easily according to the invention if a punch-laminating technology is used to produce the notch. The electronic component is preferably inserted directly into the notch and is connected therein to the second metal layer that is situated underneath and through which heat dissipation can proceed directly, in contrast to the first metal layer. The heat can be transferred from the at least one electronic component either directly into the second metal layer or through a connecting means that conducts electrical current and is a good heat conductor, such as copper or copper alloys. The flow of heat therefore only needs to overcome one or two boundary layers. Each boundary layer preferably scatters photons and thus acts as a thermal resistance. Accordingly, reducing the number of boundary layers, and thus the number of thermal barriers, effects improved coupling of electronic components and thus stronger cooling of the electronic components. Electronic components that are cooled better have a longer service life and can work more efficiently. The invention therefore also effects an improvement of the heat management, since the heat generated at the electronic component can be dissipated directly through the through-plating. A laminate produced according to the invention or a laminate according to the invention thus enables the use of electronic components with high power which cannot yet be used in very flat laminates. Specifically, the connecting means (solder, conductive adhesive, sintering compound or welding) can be utilized to produce a heat-conducting and electrically conductive connection of the two metal layers or to directly connect the component to the second metal layer.

Moreover, it is advantageous for the embossing or the bulging in the first metal layer to be sufficiently large to accommodate the electronic component such that the electronic component can be inserted into the embossing or the bulging. For this purpose, not only the conductor connectors need to be accommodated, but rather it must be feasible to lower the entire electronic component into the embossing or bulging, at least partly.

In this context, the general physical conditions required for incorporation of the electronic component can also be suitable for embossing of the first metal layer and/or formation of the through-plating of the two metal layers. This allows the incorporation of the electronic component and the production of the through-plating to be implemented in a single manufacturing step. It also allows to ensure that the electronic component is positioned at the desired site. The force required to insert or press-in the electronic component is thus simultaneously used to produce the embossing and/or for deep-drawing the first metal layer.

Moreover, the connecting means used to contact and connect the electronic component to the metal layers can also be used to support the entire structure.

The measures according to the invention achieve a low design height of the laminate including the integrated electronic components, since the electronic component or electronic components are sunk at least partly into the embossing and/or bulging. Shaping the embossings and/or bulgings appropriately allows their walls to be utilized for reflection of radiation to be measured onto a sensor as the electronic component or for reflection of emitted radiation of an emitter, such as an LED as electronic component.

Aside from the improved dissipation of heat of the electronic components, laminates produced according to the invention also simplify the design and connection technology for the electronic component.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

Exemplary embodiments of the invention shall be illustrated in the following on the basis of three schematic figures, though without limiting the scope of the invention. In the drawings:

FIG. 1 shows a schematic cross-sectional view of a laminate according to an embodiment of the invention;

FIG. 2 shows a schematic cross-sectional view of a second laminate according to an embodiment of the invention; and

FIG. 3 shows a schematic cross-sectional view of a third laminate according to an embodiment of the invention.

### DETAILED DESCRIPTION OF THE INVENTION

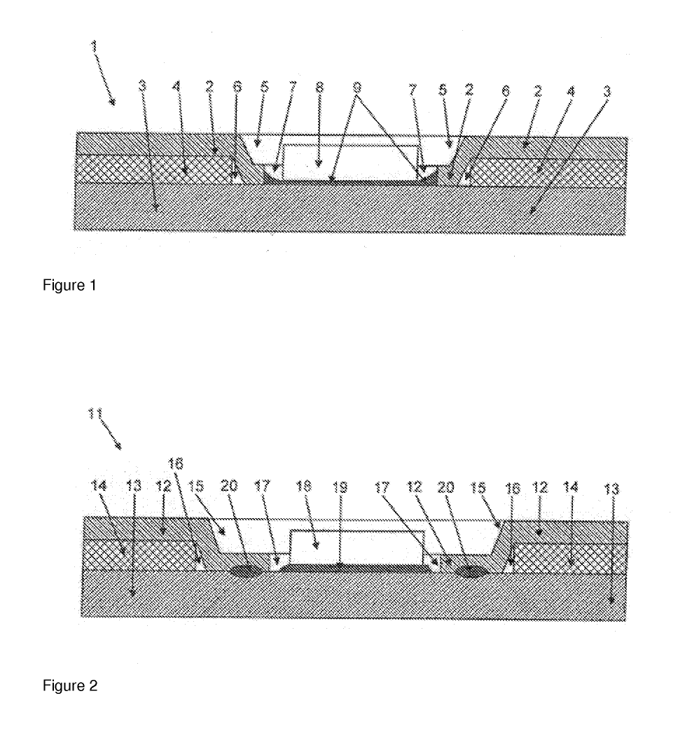

FIG. 1 shows a schematic cross-sectional view of a laminate 1 according to an embodiment of the invention or, as it may be, a schematic cross-sectional view of a laminate 1 produced using a method according to an embodiment of the invention. Laminate 1 comprises a first metal layer 2, a second metal layer 3, and an insulator 4 as insulating layer between the two metal layers 2, 3. The metal layers 2, 3 are applied to the insulator 4 by means of lamination technology.

An embossing 5 produced by means of embossing, deep-drawing or any other forming technique in a previously planar metal layer 2 is provided in the first metal layer 2. Alternatively, a bulging 5 can be provided that is produced during production of the first metal layer 2. Accordingly, a bulging 5 can also be produced alternatively by means of conferring a corresponding shape to the first metal layer 2 right away. For this purpose, the first metal layer 2 can be applied, for example, onto a corresponding mould or directly to the insulator 4, for example through vapor deposition or casting.

A recess 6 is provided in the region of the embossing or bulging 5 in the insulator 4, and a notch 7 is provided in the first metal layer 2. The recess 6 in the insulator 4 can be provided either beforehand or can be generated concurrent to the deformation of the first metal layer 2. Preferably, producing the laminate 1, in particular connecting the metal layers 2, 3 to the insulator 4, is implemented concurrent to the formation of the embossing or bulging 5 and the formation of the notch 7 in the first metal layer 2 in a single step. According to an embodiment of the invention, the application of a punch-lamination technology is particularly well-suited for this purpose.

The embossing or bulging 5 has an electronic component 8 arranged in it that is connected in conductive manner on its bottom-side to the second metal layer 3 through connecting means 9. Solders, conductive adhesives, and conductive sintering compounds are conceivable connecting means 9. The electronic component 8 can be a chip, an LED, an integrated circuit, in particular power circuits such as transistor circuits, or a sensor. Conceivable sensors are, for example, photodiodes, phototransistors or stress-strain sensors. Due to the depression formed jointly through the embossing or bulging 5 and the recess 6 and notch 7, the electronic component 8 is situated in laminate 1 such as to be protected. The height H of the electronic component 8 is less than the depth of the embossing 5 or of the bulging 5, as is evident from the upper perspective line indicating the upper edge of the embossing or bulging 5 behind the electronic component 8.

Aside from the bottom-side contacting by means of the connecting means 9, the electronic component 8 can be connected at its top to the power supply and/or circuitry using one or more bonding wires. The connecting means 9 also serves to connect the first metal layer 2 to the second metal layer 3 in conductive manner. This allows a particularly simple production method to be selected, as is illustrated through the following exemplary embodiment without limiting the scope of the invention.

The two metal layers 2, 3 are, for example, glued as metal foils to the two sides of the insulator 4, which, for example, is a PET layer. Subsequently, the metal foils are laminated to the PET layer by means of punch-laminating technology. During this process, part of the PET layer is punched out to form the recess 6 in the insulator 4 and part of the metal foil is punched out of the first metal layer 2 to form the notch 7. During this process, the upper metal foil, which is to be the first metal layer 2, is being embossed and/or deformed. Concurrently, the electronic component 8 can be glued or soldered into the structure. In this context, the temperature required for soldering and the pressure required for punching out the recess 6 and the notch 7 for the purpose of embossing or deformation and for inserting the electronic component act in concert and jointly support the formation of the desired laminate 1 with integrated electronic component 8. The embossing 5 or separation of the first metal layer 2 can be carried out while the electronic component 8 is being inserted and connected. The formation of the laminate 1 according to the invention can thus be carried out essentially in one procedural step according to the invention which is associated with additional production advantages such as cost reduction.

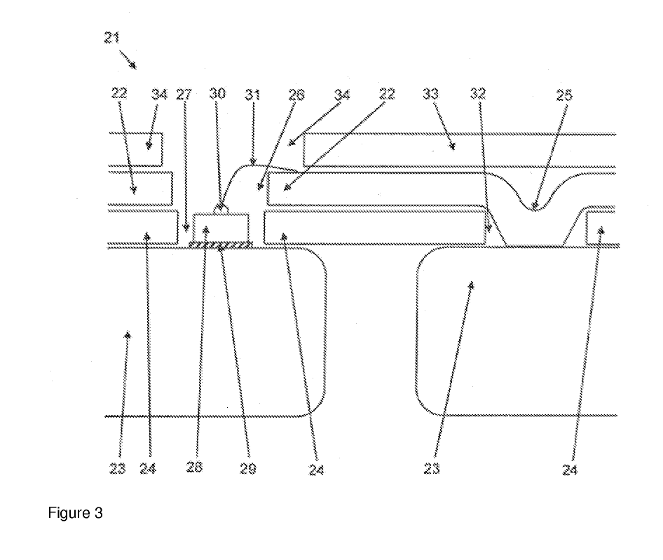

FIG. 2 shows a schematic cross-sectional view of another laminate 11 according to an embodiment of the invention or, as it may be, of another laminate 11 that is built-up using a method according an embodiment of to the invention. The structure of laminate 11 resembles that of laminate 1 illustrated based on FIG. 1. As before, a first metal layer 12 and a second metal layer 13 are separated from each other through an insulating layer 14. The insulating layer 14 can be made, for example, of a dielectric, such as, for example, plastic material, PET, glass or a glass fibre-epoxy compound material.

The first metal layer 12 comprises an embossing 15 or a bulging 15. A recess 16 is arranged in the insulating layer 14. A notch 17 that breaks through the surface of the first metal layer 12 is arranged within the embossing 15 or recess 15 in the first metal layer 12. The embossing 15 or the notch 15 is arranged in the recess 16 of the insulating layer 14.

An electronic component 18 is arranged in the notch 15 and is connected on its bottom side in electrically conductive manner to the second metal layer 13 by means of a first connecting means 19. According to the invention, the first connecting means 19 could just as well be connected, additionally, to the first metal layer 12, though this is not obligatory according to the invention. On its top, the electronic component 18 can be connected to at least one bonding wire (not shown) that contacts the electronic component 18.

The two metal layers 12, 13 are welded together directly to each other in the region of the embossing 15 or bulging 15. A laser beam welding technique, for example, is well-suited for this purpose. However, any other connecting techniques can be used as well to produce a conductive connection, such as, for example, soldering, gluing with a conductive adhesive or sintering with a conductive sintering compound (for example a silver sintering compound). The two metal layers 12, 13 are therefore connected to each other through a conductive second connecting means 20.

The laminate 11 shown can essentially be produced in one production step despite the additional second connecting means 20. In order to form the connecting site 20, it is only necessary to apply solder once and/or to perform one welding in addition to the first connecting means 19.

FIG. 3 shows another laminate 21 according to an embodiment of the invention and/or another laminate 21 that was produced by means of a method according to an embodiment of the invention. The laminate 21 is essentially made up of a thin upper first metal layer 22 and a thicker lower second metal layer 23 between which an insulating plastic layer 24 is arranged. The second metal layer 23 is interrupted appropriately such that the two parts of the second metal layer 23 are not connected to each other in electrically conductive manner.

The first metal layer 22 comprises an embossing 25 or a bulging 25 at which the distance between the first metal layer 22 and the second metal layer 23 is reduced to the extent to render the two metal layers 22, 23 connected to each other in electrically conductive manner. In addition, the two metal layers 22, 23 can be welded, soldered or sintered to each other at the embossing 25 or bulging 25.

A first recess 26 in the plastic layer 24 is provided above the left part of the second metal layer 23. The first metal layer 22 also has a notch 27 at this site. An electronic component 28 is arranged in the recess 26 and the notch 27 and is connected to the second metal layer 23 by means of a conductive adhesive 29 serving as connecting means. The conductive adhesive 29 conducts not only electrical current, but also heat from the electronic component 28 into the second metal layer 23. The thickness of the second metal layer 23 being high as compared to the electronic component 28 allows the second metal layer 23 to act as a heat sink. Since the heat capacity of the part of the second metal layer 23 that is connected to the electronic component 28 is very high as a result of its extension and thus of its mass, the electronic component 28 can be cooled effectively. Moreover, the thin layer of conductive adhesive is just a small heat resistance for heat conduction from the electronic component 28 to the second metal layer 23. The heat-sensitive electronic component 28 (such as, for example, a chip) is placed directly onto the lower second metal layer 23 (for example by means of silver conductive adhesive). This minimizes the contact resistances and attains direct coupling to the heat capacity of the second metal layer 23.

For electrical contacting of the electronic component 28, the top of the electronic component 28 has arranged on it a contacting 30 to which a bonding wire 31 is attached that connects the contacting 30, and thus the electronic component 28, to the first metal layer 22 in electrically conductive manner. A second recess 32 is provided in the region of the embossing 25 or bulging 25 in the plastic layer 24 above the right part of the second metal layer 23.

A second plastic layer 33 is laminated to the top of the first metal layer 22. The purpose of the second plastic layer 33 is to protect the laminate 21 and it can also improve the optical appearance thereof in that a dyed plastic material is used for formation of the second plastic layer 33. A recess 34 is arranged in the second plastic layer 33 in the region of the first recess 26 in the first plastic layer 24 and of the notch 27 in the first metal layer 22. The recesses 27 and 34 as well as the notch 27, which act in concert to form a depression, are dimensioned appropriately such that they can easily accommodate the electronic component 28.

The first metal layer 22 being thin simplifies the through-plating in the region of the embossing 25 or bulging 25 and also simplifies the implementation of the electronic circuit due to the geometry being smaller (fin and slit widths, bonding). Desired connecting surfaces can be provided on the bottom side of the laminate 21.

Provided the electronic component 8, 18, 28 is an LED, the walls of the embossing 5, 15 or bulging 5, 15 and/or notch 7, 17, 27 formed through the first metal layer 2, 12, 22 act as reflectors for the light emitted by the LED. If the embossing 5, 15 or bulging 5, 15 and/or the notch 7, 17, 27 are produced using a suitable tool, their reflection properties can thus be influenced in a targeted manner and can thus be optimized. For example, the angles of the side walls of an embossing 5, 15, bulging 5, 15, notch 7, 17, 27 and/or recess 6, 16, 26, 34 can be established suitably such that the light emitted by the LED is directed in a certain direction, for example perpendicular to the first metal layer 2, 12, 22. The same principle can be applied in reverse as well provided the electronic component 8, 18, 28 is a light sensor or a photosensor. The light and/or the electromagnetic radiation is then reflected onto the sensor by the walls of the embossing 5, 15, bulging 5, 15, notch 7, 17, 27, and/or recess 6, 16, 26, 34. If an embossing stamp is used for embossing and the stamp is polished to be of optical quality, the stamp can produce a particularly smooth wall surface such that undesired scattering of the incident or emergent radiation is minimized.

The laminates 1, 11, 21 having an integrated electronic component 8, 18, 28 illustrated on the basis of the figures can easily be extended to laminates 1, 11, 21 having multiple embossings 5, 15, 25, bulgings 5, 15, 25, notches 7, 17, 27 and/or recesses 6, 16, 26, 34, through arranging the structures shown in the figures in any way next to each other or in sequence (relative to the image plane of FIGS. 1 to 3). In this case, identical or different electronic components 8, 18, 28 are then arranged in the various embossings 5, 15, 25, bulgings 5, 15, 25, notches 7, 17, 27, and/or recesses 6, 16, 26, 34. In this context, the metal layers 2, 12, 22 can be contacted to each other in various ways or can be separate from each other. Accordingly, the electronic components 8, 18, 28 can be circuited in series or parallel.

For improved dissipation of heat, the lower second metal layer 3, 13, 23 can be designed to be thicker. Likewise, active cooling of the second metal layer 3, 13, 23, for example through Peltier elements, air cooling or liquid cooling, is conceivable just as well. Upon suitable selection of the metal layers 2, 3, 12, 13, 22, 23 and insulating layers 4, 14, 24, 33, the laminates 1, 11, 21 can be made to be flexible and mobile. Moreover, based on the lamination, good corrosion resistance, solder bath resistance, and mechanical stability can be attained. A layer 33 being applied additionally allows the optical appearance of the laminates 1, 11, 21 to be improved.

The features of the invention disclosed in the preceding description and in the claims, figures, and exemplary embodiments, can be essential for the implementation of the various embodiments of the invention both alone and in any combination.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-16. (canceled)

17. A method for producing a laminate (1, 11, 21) for contacting at least one electronic component (8, 18, 28) in which an insulating layer (4, 14, 24) is arranged between a first metal layer (2, 12, 22) and a second metal layer (3, 13, 23), the method comprising:
contacting the first and second metal layers (2, 3, 12, 13, 22, 23) to each other in at least one contact region;
generating at least one recess (6, 16, 26) in the insulating layer (4, 14, 24);
laminating the metal layers (2, 3, 12, 13, 22, 23) to the insulating layer (4, 14, 24);
generating at least one notch (7, 17, 27) for accommodating the at least one electronic component (8, 18, 28) in the first metal layer (2, 12, 22);
inserting the at least one electronic component (8, 18, 28) in at least one depression in the laminate (1, 11, 21) formed through the at least one notch (7, 17, 27) and the at least one recess (6, 16, 26) and connecting the at least one electronic component (8, 18, 28) in a conductive manner to the second metal layer (3, 13, 23), such that an entire circumference of the electronic component (8, 18, 28) is accommodated fully in the at least one recess (6, 16, 26) and/or notch (7, 17, 27) and at least part of a height (H) of the electronic component (8, 18, 28) is accommodated in the at least one notch (7, 17, 27) and/or recess (6, 16, 26).

18. The method according to claim 17, wherein at least one embossing (5, 15, 25) and/or at least one bulging (5, 15, 25) in the at least one contact region is generated at least in the first metal layer (2, 12, 22), and wherein a distance between the first and second metal layers (2, 3, 12, 13, 22, 23) in a region of the at least one embossing (5, 15, 25) and/or bulging (5, 15, 25) is reduced.

19. The method according to claim 18, wherein dimensions of the at least one embossing (5, 15, 25) and/or of the at least one bulging (5, 15, 25) are sufficient for accommodating the at least one electronic component (8, 18, 28), and wherein the at least one notch (7, 17, 27) is arranged in the first metal layer (2, 12, 22) in the region of the at least one embossing (5, 15, 25) and/or the at least one bulging (5, 15, 25).

20. The method according to claim 18, wherein the entire circumference of the at least one electronic component (8, 18, 28) is accommodated in the at least one embossing (5, 15, 25) and/or the at least one bulging (5, 15, 25), and wherein at least part of the height (H) of the electronic component (8, 18, 28) is accommodated in the at least one embossing (5, 15, 25) or the at least one bulging (5, 15, 25).

21. The method according to claim 17, wherein the first and second metal layers (2, 3, 12, 13, 22, 23) are connected to the insulating layer (4, 14, 24) by punch-lamination while concurrently producing at least one embossing (5, 15, 25), at least one bulging (5, 15, 25) and/or the at least one notch (7, 17, 27).

22. The method according to claim 17, wherein the first and second metal layers (2, 3, 12, 13, 22, 23) are connected to each other and/or the at least one electronic component (8, 18, 28) is connected to at least one of the first and second metal layers (3, 13, 23) by welding, soldering, gluing with a conductive adhesive (9, 19, 29) or sintering in the at least one contact region.

23. The method according to claim 18, wherein the at least one embossing (5, 15, 25) and/or the at least one bulging (5, 15, 25) in the first metal layer (2, 12, 22) is produced in the same step in which the at least one electronic component (8, 18, 28) is contacted to the first metal layer (2, 12, 22).

24. The method according to claim 17, wherein the at least one electronic component (8, 18, 28) is connected across much of its surface area to the second metal layer (3, 13, 23) and is thermally well-coupled to the second metal layer (3, 13, 23).

25. The method according to claim 18, wherein the at least one embossing (5, 15, 25), the at least one bulging (5, 15, 25), the at least one notch (7, 17, 27) and/or the at least one recess (6, 16, 26) is/are shaped such that angles of side walls with respect to the first metal layer (2, 12, 22) are adjusted such that light is emitted in one direction perpendicular to a plane of the first metal layer (2, 12, 22), and wherein a light emitting diode (LED) is inserted as the at least one electronic component (8, 18, 28) or LEDs are inserted as electronic components (8, 18, 28).

26. The method according to claim 17, wherein the second metal layer (3, 13, 23) is thicker than the first metal layer (2, 12, 22), the second metal layer (3, 13, 23) is selected to be large as compared to the at least one electronic component (8, 18, 28), and at least one of the first and second metal layers (2, 3, 12, 13, 22, 23) is made from at least one of copper, aluminium and a copper alloy.

27. The method according to claim 17, wherein at least one region of the first metal layer (2, 12, 22) is separated such that at least two regions of the first metal layer (2, 12, 22) are arranged at a distance from each other and electrically insulated from each other, and wherein the at least one electronic component (8, 18, 28) is connected to the at least two regions in a conductive manner, such that applying a voltage between the at least two regions leads to an electrical current being conducted through the at least one electronic component (8, 18, 28).

28. A laminate for contacting an electronic component (8, 18, 28) comprising:
a first metal layer (2, 12, 22);
a second metal layer (3, 13, 23) arranged essentially parallel to the first metal layer (2, 12, 22), the second metal layer (3, 13, 23) being separated from the first metal layer (2, 12, 22) through an insulating layer (4, 14, 24) in regions;
at least one recess (6, 16, 26) provided in the insulating layer (4, 14, 24); and
at least one notch (7, 17, 27) provided in the first metal layer (2, 12, 22), at least one region of the at least one recess (6, 16, 26) and the at least one notch (7, 17, 27) overlapping to form at least one depression;
at least one electronic component (8, 18, 28) arranged in the at least one depression, the at least one electronic component (8, 18, 28) being taken up entirely with respect to its circumference in the at least one notch (7, 17, 27) and/or the at least one recess (6, 16, 26), the at least one electronic component (8, 18, 28) being connected to the second metal layer (3, 13, 23) in a conductive manner, and at least a part of a height (H) of the at least one electronic component (8, 18, 28) being taken up in the at least one notch (7, 17, 27) and/or the at least one recess (6, 16, 26).

29. The laminate according to claim 28, wherein the first metal layer (2, 12, 22) comprises at least one embossing (5, 15, 25) and/or at least one bulging (5, 15, 25), the at least one notch (7, 17, 27) being arranged in the at least one embossing (5, 15, 25) and/or the at least one bulging (5, 15, 25), the first and second metal layers (2, 3, 12, 13, 22, 23) being connected in an electrically conductive manner in a region of the at least one embossing (5, 15, 25) and/or the at least one bulging (5, 15, 25).

30. The laminate according to claim 28, wherein the at least one electronic component (8, 18, 28) is a chip, a light emitting diode (LED), and/or a sensor.

31. The laminate according claim 28, wherein the second metal layer (3, 13, 23) is thicker than the first metal layer (2, 12, 22) and is large as compared to the at least one electronic component (8, 18, 28), and wherein the first and second metal layers (2, 3, 12, 13, 22, 23) comprise at least one of copper, aluminium and/or a copper alloy.

32. A device comprising the laminate according to claim 29, the device being one of a circuit board, a sensor, an LED lamp, a mobile phone component, a control, a regulator and a mobile phone flash LED.
